(19) United States
(12) Patent Application Publication
(10) Pub. No.: US 2002/0125519 A1
(43) Pub. Date: Sep. 12, 2002

(54) Capacitor of semiconductor device and manufacturing method for the same

(76) Inventors: Seung Woo Shin, Kyoungki-do (KR); Hyuk Ryun Kim, Seoul (KR)

Correspondence Address: PILLSBURY WINTHROP, LLP, P.O. BOX 10500, MCLEAN, VA, 22102, US

(21) Appl. No.: 10/028,976

(22) Filed: Dec. 28, 2001

(30) Foreign Application Priority Data
Dec. 29, 2000 (KR) 2000-86302

(51) Int. Cl. H01L 27/108; H01L 29/76

(52) U.S. Cl. 257/296

(57) ABSTRACT

The present invention generally relates to a capacitor of a semiconductor device and a method of manufacturing such capacitors that improve the processing yield and the reliability of device operation by forming the plate electrode from a p-type polysilicon, thereby improving device resistance to write operation failures resulting from concentration of holes in the plate electrode terminal during a data write operation.

### BACKGROUND OF THE INVENTION

1. Field of the Invention

The present invention generally relates to a capacitor of a semiconductor device and a method for manufacturing such capacitors that improves the reliability of processing yield and device operation by forming a plate electrode with p-type polysilicon layer and thereby preventing a write operation failure resulting from concentration of holes in the plate electrode terminal during a data write operation.

2. Description of the Prior Art

Recently, it has become more difficult to form a capacitor with sufficient capacitance due to reductions in cell size resulting from increasingly high integration levels in semiconductor devices.

Particularly in Dynamic Random Access Memory ‘DRAM’ devices consisting of a MOS transistor and a capacitor, it is important to fabricate a capacitor, which typically occupies the majority of the space in each memory cell, that has a large capacitance but uses as little space as possible.

Currently, capacitors having a polysilicon conductor typically use an oxide film, a nitride film or stacked layers thereof, such as an oxide-nitride-oxide ‘ONO’ structure, as a dielectric layer.

In order to increase capacitance, determined by the equation:

(ε₀×εᵣ×A)/T

(where ε₀ is the permittivity of free space, εᵣ is the dielectric constant of the dielectric film, A is the surface area of the capacitor, and T is the thickness of the dielectric film), the general practice has been to use dielectric materials with a high dielectric constant, reduce the thickness of dielectric film; and/or increase the effective surface area of the capacitor.

However, each of these methods has problems. First, it is difficult to implement a device using a dielectric with a high dielectric constant such as Ta₂O₅, TiO₂, or SrTiO₃ to production devices since the reliability and the characteristics of the thin film, such as a junction breakdown voltage of Ta₂O₅, TiO₂, or SrTiO₃ are not reliably known. The method of reducing the thickness of a dielectric film has a problem of deteriorating the reliability of a capacitor since the dielectric film is more easily destroyed during the device operation.

In order to increase a surface area of the capacitor, capacitors have been formed as multilayer structures of polysilicon layers that are penetrated and connected to act as fin structures or by forming a storage electrode in the shape of an open cylinder in the upper part of contact. However, if the height of a capacitor is increased, subsequent processing becomes difficult due to the stepped topography and obtaining high capacitance becomes difficult due to the decreased surface area of the device available to form such structures in highly integrated DRAMs.

A design in which the number of cells is more than twice that of the conventional cells per bit line has been used to increase the capacitance of cell capacitor in order to improve cell efficiency. However, since the available surface area for a capacitor is decreased, conventional fin or cylinder type capacitors typically attempt to increase the effective surface area by increasing the height of a capacitor, decreasing the gap between storage electrodes, or using hemispherical grain ‘HSG’ silicon.

### SUMMARY OF THE INVENTION

The present invention overcomes the above-mentioned problems of the prior art and provides a capacitor for semiconductor devices and method of manufacturing such capacitors that improves the operational characteristics of the resulting devices, by making holes the main carriers and concentrating them at the ends of the plate electrodes, thereby preventing decreased capacitance when 0V is applied to a storage electrode and +V_{cc}/2 to a plate electrode during a “0” data write.

The present invention is also characterized in forming the p-type polysilicon layer by one of a variety of doping methods including doping an initially undoped polysilicon layer by ion-implanting B or BF₂; by making B₂H₆, BF₃ or BCl₃ react with O₂ to form a B-doped oxide on the polysilicon layer and then diffusing B from the oxide into a polysilicon layer; by coating and diffusing liquid source BBr₃ or (CH₂O)₃B; or by making B₂H₆, BF₃ or BCl₃ react with SiH₄ or Si₂H₆ in a CVD chamber to produce B-doped polysilicon.

### BRIEF DESCRIPTION OF THE DRAWINGS

The objects and aspects of the present invention will become apparent from the following description of embodiments with reference to the accompanying drawings in which:

FIG. 1a is a cross-sectional view illustrating a conventional method of forming an electrode of a capacitor.

FIG 1b is a cross-sectional view illustrating another conventional method of forming an electrode of a capacitor.

FIGS. 2a and 2b are cross-sectional views illustrating depletion and accumulation states in the conventional capacitor.

FIG. 3 is a cross-sectional view illustrating a “1” data write operation of a conventional capacitor.

FIG. 4 is a cross-sectional view illustrating a “0” data write operation of a conventional capacitor.

FIG. 5 is a graph illustrating capacitance according to a bias voltage of the conventional capacitor.

FIG. 6 is a cross-sectional view illustrating a capacitor in accordance with the present invention.

### DETAILED DESCRIPTION OF THE PREFERRED EMBODIMENTS

Generally, a storage electrode and a plate electrode are formed of an n-typed polysilicon layer doped with phosphorus ‘P’.

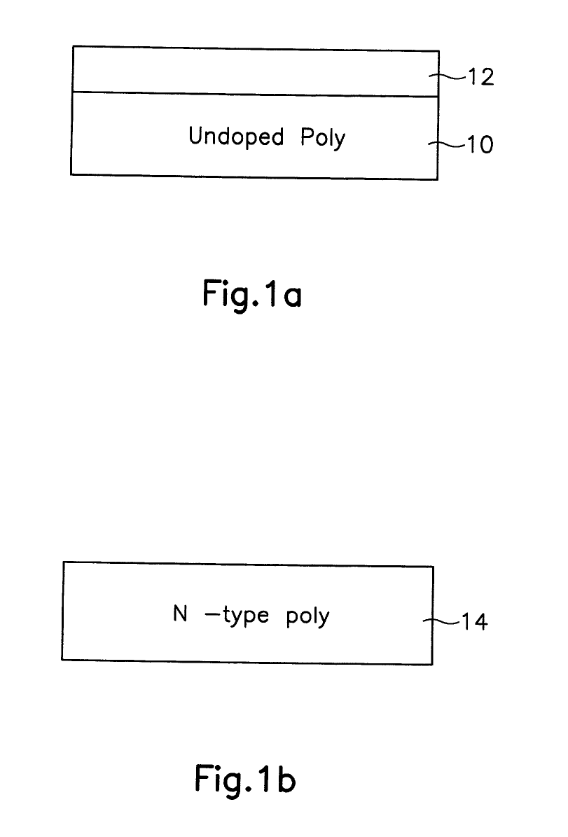

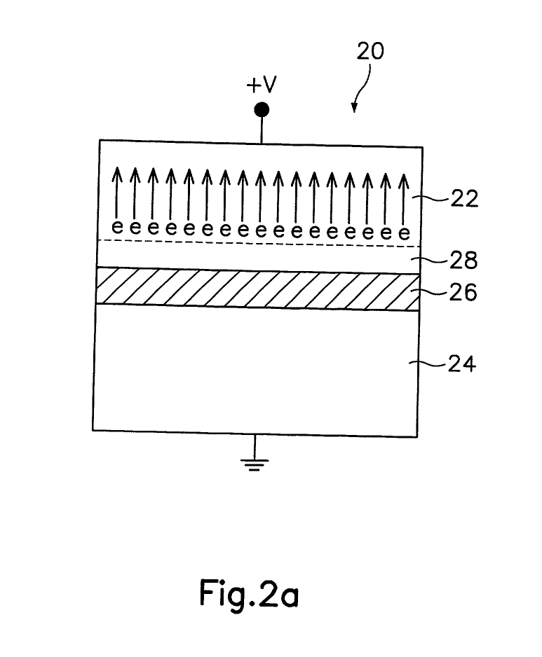

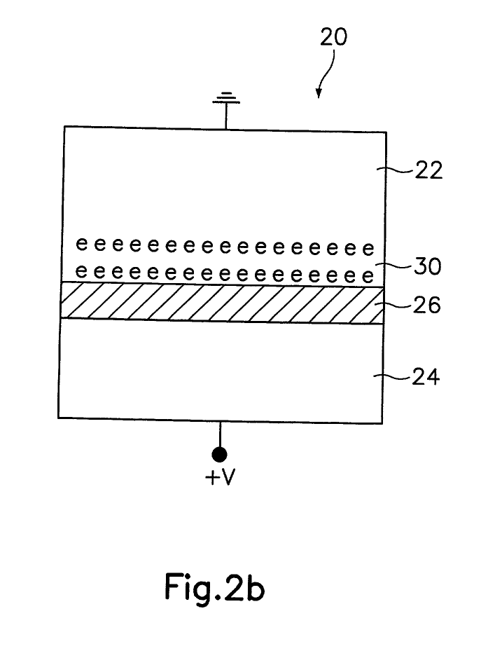

FIG. 1a is cross-sectional view illustrating a conventional capacitor electrode and FIG. 1b is a cross-sectional view illustrating another conventional capacitor electrode. FIG. 2a and FIG. 2b are cross-sectional views illustrating depletion and accumulation phenomena of the conventional capacitor.

FIG. 1a is a conventional method of forming an electrode of a capacitor. A undoped polysilicon layer 10 is formed and then a P₂O₅ film 12 is formed on the polysilicon layer 10 by exposing the polysilicon layer 10 to a gaseous doping source in a diffusion chamber. P of the P₂O₅ film is diffused into the polysilicon layer, forming an n-typed polysilicon layers, and then the P₂O₅ 12 is removed.

Here, a gas mixture of POCl₃ and O₂ is used as the doping source.

FIG. 1b illustrates another conventional method of forming an electrode of a capacitor. By performing Chemical Vapor Deposition process using a gas mixture of either SiH₄ and PH₃ or Si₂H₆ and PH₃ or a combination thereof, a P-doped polysilicon layer 14 is formed.

As shown in FIG. 2a, an electrode of a capacitor 20 formed by the conventional method comprises a storage electrode 22 which is an n-type polysilicon layer, the main carrier of which is an electron, a plate electrode 24 separated by a dielectric film 26. When a positive (+) voltage is applied to the storage electrode 22, a depletion of the main carrier occurs and a depletion region 28 is formed. Also, as shown in FIG. 2b, when a positive voltage is applied to the plate electrode 24, an electron accumulation occurs and an accumulation region 30 is formed.

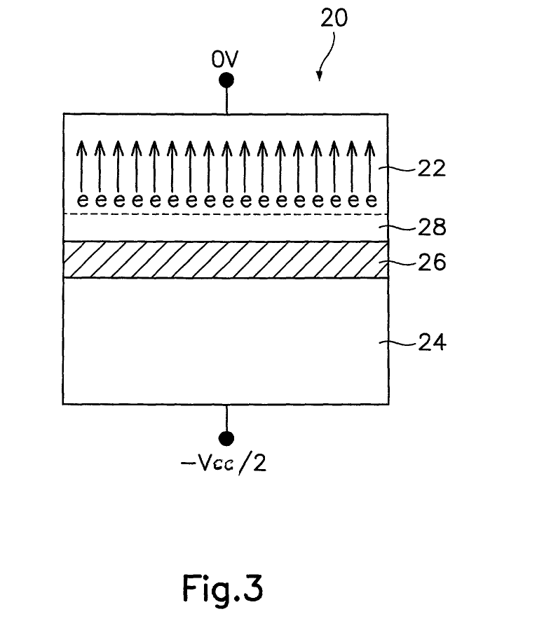

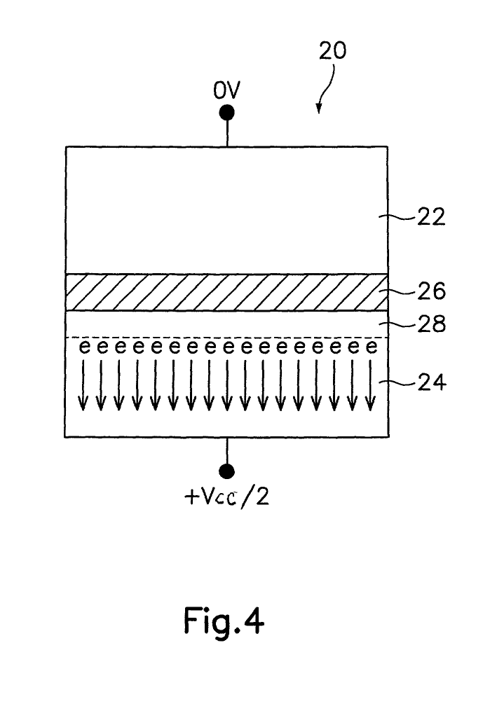

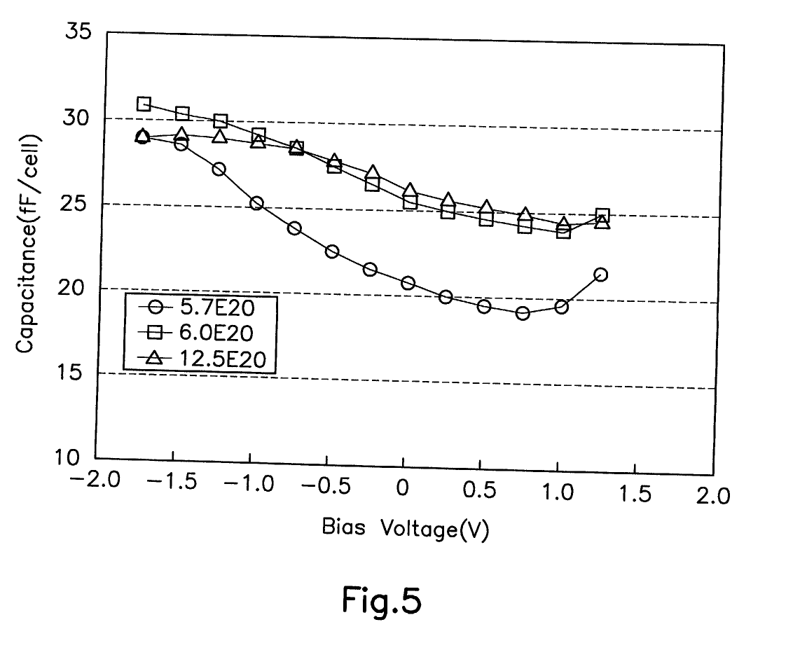

These characteristics of an operation of a capacitor are as follows: FIG. 3 is a cross-sectional view illustrating a “1” data write operation of the conventional capacitor, FIG. 4 is a cross-sectional view illustrating a “0” data write operation, and FIG. 5 is a capacitance graph in accordance with a bias voltage of the conventional capacitor.

First, when storing a data “1” in a capacitor 20, 0V is applied to a storage electrode 22 and—Vₛₛ/2 to a plate electrode 24, and, as shown in FIG. 3, more depletion occurs closer to the interface of the storage electrode 22 and the dielectric 26. When storing a data “0” in the capacitor 20, 0V is applied to the storage electrode 22 and +V_{cc}/2 to the plate electrode 24. As a result, as shown in FIG. 4, a depletion region 28 is formed close to the interface of the plate electrode 24 with the dielectric 26.

As described above, when the impurity concentration is not fully saturated, the depletion phenomenon is intensified as the voltages applied to electrodes increase in electrodes of capacitor formed by the conventional method. As shown in FIG. 5, when the amount of the impurity dose is small, the desired capacitance of approximately 25 fF cannot be obtained and write operation failures occur. There is a limit in increasing the amount of doping in order to prevent the depletions mentioned above.

Because the lower storage electrode is formed with a higher aspect ratio during manufacturing process of plate electrodes, phosphorus, with its relatively lower turnover rate compared to Si, cannot move fully into the inside of the electrode, thereby decreasing doping concentration of electrodes actually formed.

The problem described above cannot be overcome since the aspect ratio increases are necessary to maintain capacitance as devices become smaller and the distance between storage electrodes decreases.

Hereafter, a capacitor of a semiconductor device and manufacturing method for the same will be explained in detail referring to the attached drawings.

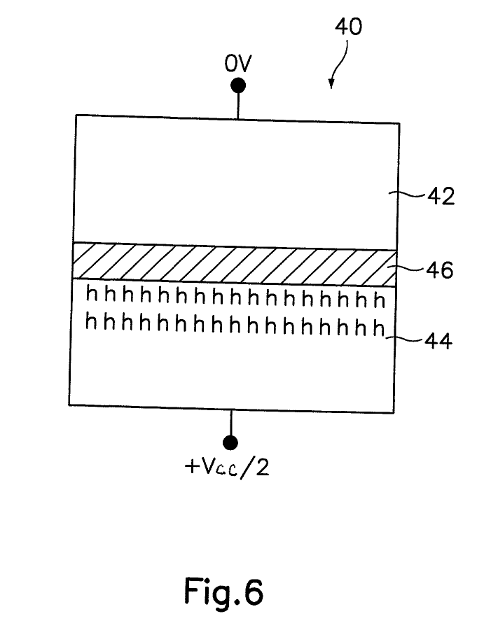

FIG. 6 is a cross-sectional view of a capacitor formed in accordance with the present invention. A capacitor comprises a storage electrode 42 formed of an n-type polysilicon layer, a plate electrode 44 formed of a p-type polysilicon layer separated by a dielectric film 46.

Since the main carriers of plate electrode 44 are holes as a result of forming plate electrode 44 of the capacitor 40 from a p-type polysilicon layer, holes are concentrated on the ends of the plate electrode and a capacitance does not decrease when 0V is applied to a storage electrode and +V_{cc}/2 to a plate electrode during the write operation of data “0” write to the capacitor. As a result, the reliability of “0” data write operation is improved.

The p-type polysilicon layer is formed by doping B on a undoped polysilicon layer through ex-situ or in-situ methods.

As an example of ex-situ method, there is provided a first method of ion-implanting B or BF₂ after forming an undoped polysilicon layer.

There is provided a second method of forming an oxide film doped with B on the surface of the polysilicon layer by reacting B₂H₆, BF₃ or BCl₃ with O₂, and then diffusing B from oxide film into the polysilicon layer.

There is provided a third method for coating a liquid source such as BBr₃ or (CH₂O)₃B on the surface of a undoped polysilicon layer and then diffusing B into the polysilicon layer.

Also, there is provided an in-situ method of forming a p-type polysilicon layer doped with B by reacting B₂H₆, BF₃ or BCl₃ with SiH₄ or Si₂H₆ in a CVD device.

As is apparent from the above description, in accordance with the present invention, a capacitor of a semiconductor device and manufacturing method for the same is provided by forming a plate electrode from a B-doped polysilicon layer, applying 0V to a storage electrode and +V_{cc}/2 to a plate electrode when “0” data is written, thereby preventing holes, which are the main carriers in the plate electrode, from being concentrated on the ends of plate electrode. Accordingly, it is possible to prevent the degradation of capacitance, and improve processing yield, and improve the reliability of device operation.

What is claimed is:

1. A semiconductor device having a capacitor wherein the capacitor comprises:
a storage electrode comprising an n-type polysilicon;
a plate electrode comprising a p-type polysilicon; and
a dielectric material separating the storage electrode and the plate electrode.

2. A semiconductor device according to claim 1, constructed and arranged as a memory device for storing digital data,
wherein a “0” data write operation comprises applying 0V to the storage electrode and +V_{cc}/2 to the plate electrode.

3. A method of forming a capacitor in a semiconductor device, comprising steps of:
forming a storage electrode comprising a n-type polysilicon;
forming a dielectric film on the storage electrode; and
forming a plate electrode comprising p-type polysilicon on the dielectric film.

4. The method of forming a capacitor in a semiconductor device according to claim 3:
wherein the step of forming the plate electrode further comprises
forming an undoped polysilicon layer; and
implanting a predetermined dose of a p-type ionic species into the undoped polysilicon layer, the predetermined dose being sufficient to covert the undoped polysilicon layer into a p-type silicon layer.

5. The method of forming a capacitor in a semiconductor device according to claim 4:
wherein the p-type ionic species is selected from a group consisting of B⁺ and BF₂⁺.

6. The method of forming a capacitor in a semiconductor device according to claim 3:
wherein the step of forming the plate electrode further comprises
forming an undoped polysilicon layer;
forming a boron-containing oxide layer on the undoped polysilicon layer; and
diffusing a portion of the boron from the oxide layer into the undoped polysilicon layer, the portion of the boron diffused being sufficient to covert the undoped polysilicon layer into a p-type silicon layer.

7. The method of forming a capacitor in a semiconductor device according to claim 6:
wherein the step of forming the boron-containing oxide layer further comprises reacting one or more gases selected from a group consisting of B₂H₆, BF₃ and BCl₃ with oxygen gas.

8. The method of forming a capacitor in a semiconductor device according to claim 3:
wherein the step of forming the plate electrode further comprises
forming an undoped polysilicon layer;
passing a carrier gas through a boron-containing liquid to form a boron-containing doping vapor; and
heating the undoped polysilicon layer to a doping temperature while exposing the undoped polysilicon layer to the doping vapor to diffuse a quantity of boron into the undoped polysilicon layer, the quantity being sufficient to covert the undoped polysilicon layer into a p-type silicon layer.

9. The method of forming a capacitor in a semiconductor device according to claim 3:
wherein the step of forming the plate electrode further comprises
reacting at least one boron-containing gas, selected from a group consisting of B₂H₆, BF₃ and BCl₃, with at least one silicon-containing gas selected from a group consisting of SiH₄ and Si₂H₆, to form a layer of p-type polysilicon.
